(19) United States
(12) Patent Application Publication
(10) Pub. No.: US 2006/0279931 A1
(43) Pub. Date: Dec. 14, 2006

(54) CPU heat sink mount attachment structure

(76) Inventor: Yun-Hsiu Lee, Taipei Hsien (TW)

Correspondence Address: Troxell Law Office Pllc;Suite 1404, 5205 Leesburg Pike, Falls Church, VA, 22041, US

(21) Appl. No.: 11/150,137

(22) Filed: Jun. 13, 2005

(51) Int. Cl. H05K 7/20

(52) U.S. Cl. 361/704

(57) ABSTRACT

A CPU heat sink mount attachment structure embodying a retaining pin member, a spring member and an inner retaining pin, and characterized in that: the inner retaining pin and the spring member are disposed within the retaining pin member, clip arms of the inner retaining pin respectively clip within clip holes of an outer side wall of the retaining pin member. When a retaining pin protruding from a center of the inner retaining pin is pressed downward, a pin-foot positioned at a bottom of the retaining pin member is caused to prop open. According to the aforementioned structure, the present invention not only achieves rapid and convenient assembly or disassembly of a heat sink mount, moreover, effectiveness of considerable securing strength after attaching to a motherboard is assured.

### BACKGROUND OF THE INVENTION

(a) Field of the Invention

The present invention relates to a CPU heat sink mount attachment structure, and more particularly to an attachment structure assembled from a retaining pin member, a spring member and an inner retaining pin. The attachment structure can be rapidly assembled and disassembled, and enables a heat sink mount to achieve securing a CPU (central processing unit) heat sink.

(b) Description of the Prior Art

As technology changes with each passing day, speed of the CPU as used in personal computers is constantly increasing while simultaneously processing large quantities of data. After Intel Corporation officially released the LGA775 CPU, which in practice meant that the existing socket mode was no longer used, and design of the pins on the CPU were changed to ball mode, which achieved using a 775 ball design to insert within a socket of the socket T CPU and come in contact with an elastic piece within the CPU socket, and locating holes defined in a periphery of the CPU socket accommodated securing the heat sink. In order to accommodate the CPU framework, the heat sink used by the CPU has also undergone transformation, particularly the heat sink mount used to secure the heat sink, which not only must provide sufficient force to secure the heat sink, but also avoid damaging the elastic piece within the CPU socket by forcedly pressing down thereon. Referring to FIG. 1, which depicts a fastening method presently adopted by an attachment structure b of a heat sink mount a. The attachment structure b uses a combination of an inner pin b1 and an outer pin b2 to fasten a periphery of the heat sink mount a between the inner pin b1 and the outer pin b2. A bottom of the outer pin b2 is provided with a pin-foot b21, dimensions of which are slightly larger than a locating hole c1 in a periphery of a CPU socket c. A front end of the pin-foot b21 is provided with a tapered portion, and transformation in dimensions of the tapered portion when the pin-foot b21 penetrates the locating hole c1 achieves the objective of securing the heat sink mount a. Such a securing method is extremely convenient for attaching the heat sink mount a, however, it is extremely inconvenient when disassembling or replacing. Hence, there is need for an improved design.

### SUMMARY OF THE INVENTION

In light of the shortcomings of the aforementioned conventional structure, the inventor of the present invention, having accumulated years of experience in related arts, attentively and circumspectly carried out extensive study and exploration to ultimately design a new improved CPU heat sink mount attachment structure.

A primary objective of the present invention is to provide a heat sink attachment structure as used by a heat sink, which not only achieves rapid and convenient assembly or disassembly of the heat sink mount, but also effectiveness of considerable securing strength after attaching to a motherboard is assured.

In order to achieve the aforementioned objective, the CPU heat sink mount attachment structure of the present invention is primarily structured to comprise a retaining pin member, a spring member and an inner retaining pin. An interior of the retaining pin member is provided with a holding space, and an opening is defined in a bottom of the holding space, moreover, a pin-foot downwardly extends from the retaining pin member. A groove is defined along a center of the pin-foot, and clip holes are defined on an outer side wall of the retaining pin member. A retaining pin downwardly protrudes from a center of the inner retaining pin, which is used to insert within the opening at the bottom of the retaining pin member. Side walls of the inner retaining pin are provided with clip arms, and a catch inwardly extends from each of the clip arms, which are used to realize clipping within the clip holes of the retaining pin member. Moreover, a withdrawing handle upwardly and outwardly extends from an outer side of each of the clip arms.

According to the aforementioned structure, the retaining pin member is first disposed within a locating hole of a periphery of a heat sink mount, and the spring member together with the inner retaining pin are then disposed within the retaining pin member, thereby clasping the heat sink mount between the retaining pin member and the inner retaining pin. When attaching the heat sink mount to a motherboard, the pin-foot at the bottom of the retaining pin member is first aligned over a locating hole of the motherboard and then disposed therein. A top flat surface of the inner retaining pin is then pressed down, thereby fastening the clip arms of the inner retaining pin within the clip holes on the outer side wall of the retaining pin member, and after the retaining pin protruding from the center of the inner retaining pin is pressed downward, the pin-foot positioned at the bottom of the retaining pin member is caused to outwardly prop open, which thereby securely clips the retaining pin member within the locating hole of the motherboard.

When disassembly the attachment structure, two sides of the withdrawing handles on the top of the inner retaining pin need only be inwardly pressed to enable the retaining pin to spring out from the locating hole by means of the spring member, thereby restoring the pin-foot to its original state. The heat sink attachment structure of the present invention is extremely convenient to use, which not only enables rapid and convenient assembly or disassembly of the heat sink mount, moreover, the heat sink mount is fixedly secured after attaching to a motherboard.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows a structural elevational view of a conventional attachment structure.

FIG. 2 shows an exploded elevational view according to the present invention.

FIG. 3 shows a schematic view of the present invention in use (1).

FIG. 4 shows a schematic view of the present invention in use (2).

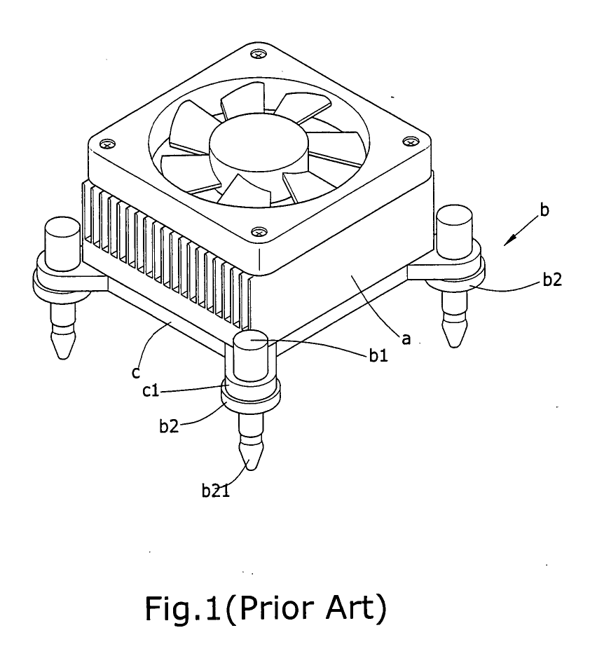

### DETAILED DESCRIPTION OF THE PREFERRED EMBODIMENTS

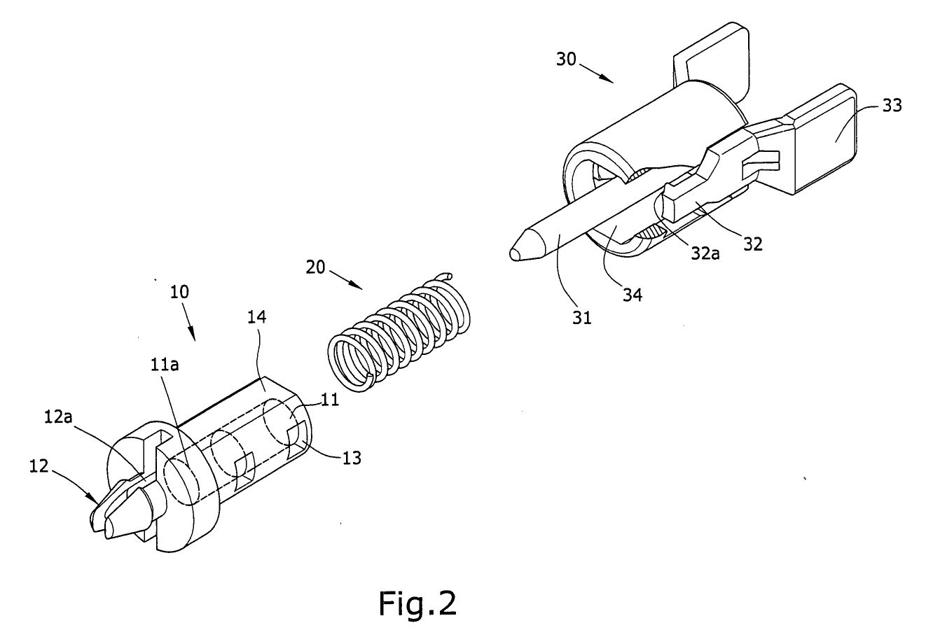

Referring to FIG. 2, which shows a CPU heat sink mount attachment structure of the present invention, primarily structured to comprise a retaining pin member 10, a spring member 20 and an inner retaining pin 30.

An interior of the retaining pin member 10 is provided with, a holding space 11, and an opening 11a is defined in a bottom of the holding space 11, moreover, a pin-foot 12 downwardly extends from the retaining pin member 10. A groove 12a is defined along a center of the pin-foot 12, and clip holes 13 are defined on an outer side wall of the retaining pin member 10. A positioning portion 14 designed to realize an anti-rotation effect is further provided on the outer side wall of the retaining pin member 10.

Interior of the inner retaining pin 30 is designed so as to correspond in shape to that of the outer side wall of the retaining pin member 10, and a retaining pin 31 downwardly protrudes from a center of the inner retaining pin 30, which is used to insert within the opening 11a at the bottom of the retaining pin member 10. Side walls of the inner retaining pin 30 are provided with clip arms 32, and a catch 32a inwardly extends from each of the clip arms 32, which are used to realize clipping within the clip holes 13 of the retaining pin member 10. Moreover, a withdrawing handle 33 upwardly and outwardly extends from an outer side of each of the clip arms 32. Furthermore, an inner side wall of the inner retaining pin 30 is provided with a positioning portion 34 to correspond with the positioning portion 14 of the retaining pin member 10.

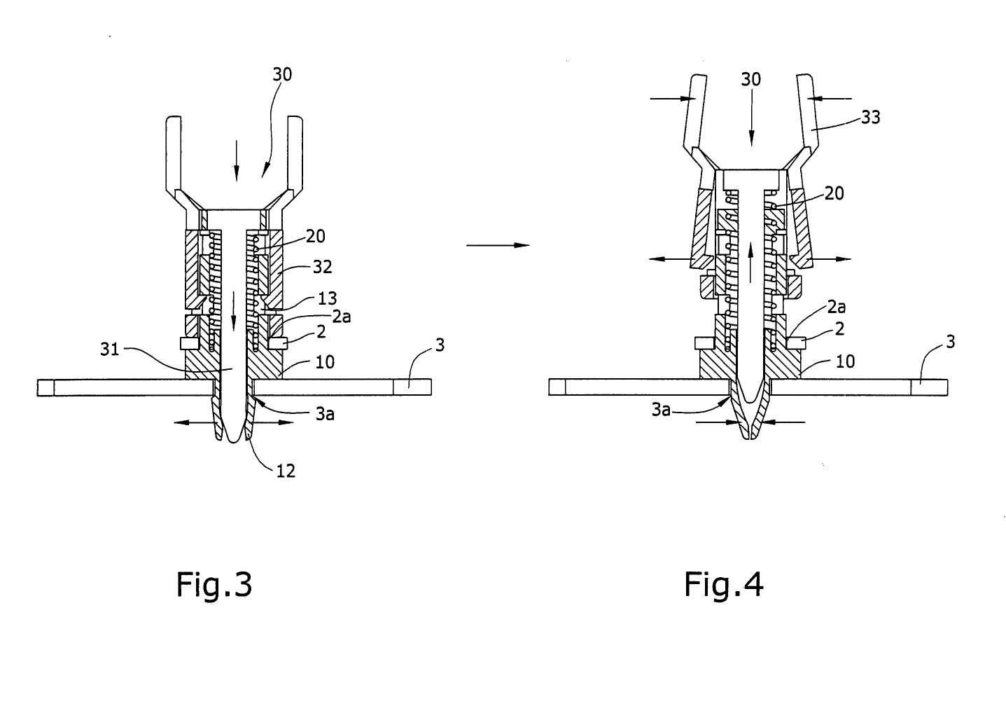

Referring to FIGS. 3 and 4, wherein the retaining pin member 10 is disposed within a locating hole 2a of a periphery of a heat sink mount 2, and the spring member 20 together with the inner retaining pin 30 are disposed within the retaining pin member 10, thereby clasping the heat sink mount 2 between the retaining pin member 10 and the inner retaining pin 30.

Referring again to FIGS. 3 and 4, when attaching the heat sink mount 2 to a motherboard 3, the pin-foot 12 at the bottom of the retaining pin member 10 is first aligned over a locating hole 3a of the motherboard 3 and then disposed therein. A top flat surface of the inner retaining pin 30 is then pressed down, thereby fastening the clip arms 32 of the inner retaining pin 30 within the clip holes 13 on the outer side wall of the retaining pin member 10, and after the retaining pin 31 protruding from the center of the inner retaining pin 30 is pressed downward, the pin-foot 12 positioned at the bottom of the retaining pin member 10 is caused to outwardly prop open, which thereby securely clips the retaining pin member 10 within the locating hole 3a of the motherboard 3. When disassembly the attachment structure, two sides of the withdrawing handles 33 on the top of the inner retaining pin 30 need only be inwardly pressed to enable the retaining pin 30 to spring out from the locating hole 3a by means of the spring member 20, thereby restoring the pin-foot 12 to its original state.

In conclusion, the CPU heat sink mount attachment structure of the present invention is structured from the retaining pin member 10, the spring member 20 and the inner retaining pin 30, which are used to secure the heat sink mount 2 between the retaining pin member 10 and the inner retaining pin 30. Furthermore, the retaining pin 31 of the inner retaining pin 30 is used to prop open the pin-foot 12 of the retaining pin member 10, and the clip arms 32 of the inner retaining pin 30 clip within the clip holes 13 of the outer side wall of the retaining pin member 10, thereby achieving rapid and convenient assembly or disassembly of the heat sink mount 2, and effectiveness of considerable securing strength after attaching to a motherboard. Moreover, practicability and advancement of the present invention clearly comply with essential elements as required for a new patent application, accordingly a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A CPU heat sink mount attachment structure, comprising a retaining pin member, a spring member and an inner retaining pin, and characterized in that: the inner retaining pin and the spring member are disposed within the retaining pin member, clip arms of the inner retaining pin respectively clip within clip holes of an outer side wall of the retaining pin member, when a retaining pin protruding from a center of the inner retaining pin is pressed downward, a pin-foot positioned at a bottom of the retaining pin member is caused to prop open.

2. The CPU heat sink mount attachment structure as described in claim 1, wherein an interior of the retaining pin member is provided with a holding space, moreover, an opening is defined in a bottom of the holding space, and the pin-foot downwardly extends from the retaining pin member; a groove is defined along a center of the pin-foot, and the clip holes are defined on an outer side wall of the retaining pin member; interior of the inner retaining pin is designed so as to correspond in shape to that of the outer side wall of the retaining pin member, and the retaining pin downwardly protrudes from the center of the inner retaining pin, which is used to insert within the opening at the bottom of the retaining pin member, side walls of the inner retaining pin are provided with clip arms, and a catch inwardly extends from each of the clip arms, which are used to realize clipping within the clip holes of the retaining pin member, moreover, a withdrawing handle upwardly and outwardly extends from an outer side of each of the clip arms; whereby the retaining pin member is disposed within a locating hole of a periphery of a heat sink mount, and then the spring member and the inner retaining pin are together disposed within the retaining pin member, thereby clasping the heat sink mount between the retaining pin member and the inner retaining pin.

3. The CPU heat sink mount attachment structure as described in claim 1, wherein the outer side wall of the retaining pin member is provided with a positioning portion designed to realize an anti-rotation effect.

4. The CPU heat sink mount attachment structure as described in claim 3, wherein an inner side wall of the inner retaining pin is provided with a positioning portion of same shape.
